(19) United States
(12) Patent Application Publication
(10) Pub. No.: US 2022/0102333 A1
(43) Pub. Date: Mar. 31, 2022

(54) CONFIGURABLE COMPUTER MEMORY ARCHITECTURE

(71) Applicant: Alibaba Group Holding Limited, Georgetown (KY)

(72) Inventors: Shuangchen LI, Sunnyvale, CA (US); Dimin NIU, Sunnyvale, CA (US); Hongzhong ZHENG, Los Gatos, CA (US)

(21) Appl. No.: 17/036,660

(22) Filed: Sep. 29, 2020

(51) Int. Cl. H01L 25/18; H01L 25/065; H01L 23/00; H01L 25/00

(52) U.S. Cl. CPC H01L 25/18; H01L 25/0657; H01L 24/08; H01L 24/80; H01L 2924/1436; H01L 2224/08145; H01L 2224/80895; H01L 2224/80896; H01L 2924/1431; H01L 25/50

(57) ABSTRACT

A configurable computer memory architecture includes a memory device that includes arrays of memory cells, word lines, column select lines, and data lines (including local and non-local data lines). One or more of the lines include a first segment and a second segment that are separated by a gap that prevents transmission of an electrical signal from the first segment to the second segment. Signals are either transmitted between the two segments or prevented from being transmitted between the two segments, depending on how the computer memory architecture is configured. In this manner, the memory device can be adapted for different use cases.

### BACKGROUND

Three-dimensional (3D) dynamic random access memory (DRAM) refers to a type of memory architecture in which DRAM dies are stacked with and electrically connected to logic dies using, for example, hybrid bonding techniques. 3D-DRAM can reduce memory access latency and increase memory access bandwidth. The sequential bandwidth of 3D-DRAM is good; however, random and fine-grain access is not, due to the lack of bank-level parallelism and high input/output (IO) wait (the time spent waiting for 10 operations to complete).

Different use cases can be more efficiently performed using 3D-DRAMs that are configured for those use cases. However, some manufacturers are reluctant to produce 3D-DRAMs that are configured for use cases that are not common, because the market for those 3D-DRAMs is small. On the other hand, manufacturers that produce 3D-DRAMs that are configured for less common use cases charge more for those 3D-DRAMs, because the 3D-DRAMs are not manufactured in large quantities.

### SUMMARY

Embodiments according to the present invention provide a solution to the problems described above. Embodiments according to the present invention pertain to a configurable computer memory architecture.

In embodiments, a configurable computer memory architecture includes a memory device that includes arrays of memory cells, word lines, column select lines, and data lines (including local and non-local data lines). The memory device may be dynamic random access memory (DRAM). One or more of the lines include a first segment and a second segment that are separated by a gap that prevents transmission of an electrical signal from the first segment to the second segment. Signals may be either transmitted between the two segments or prevented from being transmitted between the two segments, depending on how the computer memory architecture is configured.

In embodiments, the configurable computer memory architecture includes a first die that includes the memory device described above, and a second die bonded (e.g., hybrid bonded) to the first die. As such, in embodiments, the computer memory architecture may be referred to as three-dimensional DRAM (3D-DRAM) The second die can include circuits that can be used to configure the computer memory architecture. For example, a circuit on the second die can be used to connect the two segments of a line separated by a gap as described above, or to read out or read in data from a segment of a data line. In this manner, the memory device can be adapted for different use cases.

Thus, standard versions of the first die and standard versions of the second die can be fabricated, a version of the first die and a version of the second die can be bonded (e.g., hybrid bonded) to each other, and then the computer memory architecture can be configured according to how it is to be used by, for example, connecting selected line segments on the first die using the circuits on the second die. Because the first and second dies are standardized, they can be produced in larger quantities, which reduces manufacturing costs. Also, because the computer memory architecture can be configured according to its intended use, it is better suited to the functions it will perform, and so can perform those functions quickly and more efficiently. For example, latency is lowered, bandwidth is increased, and utilization is increased. Generally speaking, computer system memories (e.g., 3D-DRAMs) according to the present invention are flexible and satisfy different demands and different use cases.

These and other objects and advantages of the various embodiments of the present invention will be recognized by those of ordinary skill in the art after reading the following detailed description of the embodiments that are illustrated in the various drawing figures.

### BRIEF DESCRIPTION OF DRAWINGS

The accompanying drawings, which are incorporated in and form a part of this specification and in which like numerals depict like elements, illustrate embodiments of the present disclosure and, together with the detailed description, serve to explain the principles of the disclosure.

FIG. 1 is a block diagram illustrating a configurable computer memory architecture in embodiments according to the present invention.

FIG. 2 is a block diagram illustrating a memory device on a first die of the configurable computer memory architecture, in embodiments according to the present invention.

FIG. 3 shows an example of two lines of the memory device that are each separated into two segments, in embodiments according to the present invention.

FIG. 4 shows an example of a line of the memory device that is separated into a first segment and a second segment, in embodiments according to the present invention.

FIG. 5 further illustrates the examples of FIGS. 3 and 4, in embodiments according to the present invention.

FIGS. 6A, 6B, 6C, 6D, and 6E illustrate examples of different configurations of the computer memory architecture, in embodiments according to the present invention.

FIG. 7 includes two timelines showing sequences of signals for a conventional three-dimensional dynamic random access memory (3D-DRAM) architecture versus a 3D-DRAM configured as a pseudo-bank architecture in an embodiment according to the present invention.

FIG. 8 is a flowchart of an example of a method of configuring a computer memory architecture, in embodiments according to the present invention.

### DETAILED DESCRIPTION

Reference will now be made in detail to the various embodiments of the present disclosure, examples of which are illustrated in the accompanying drawings. While described in conjunction with these embodiments, it will be understood that they are not intended to limit the disclosure to these embodiments. On the contrary, the disclosure is intended to cover alternatives, modifications and equivalents, which may be included within the spirit and scope of the disclosure as defined by the appended claims. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The figures are not necessarily drawn to scale, and only portions of the devices and structures depicted, as well as the various layers that form those structures, are shown. For simplicity of discussion and illustration, only one or two devices or structures may be described, although in actuality more than one or two devices or structures may be present or formed. Also, while certain elements, components, and layers are discussed, embodiments according to the invention are not limited to those elements, components, and layers. For example, there may be other elements, components, layers, and the like in addition to those discussed.

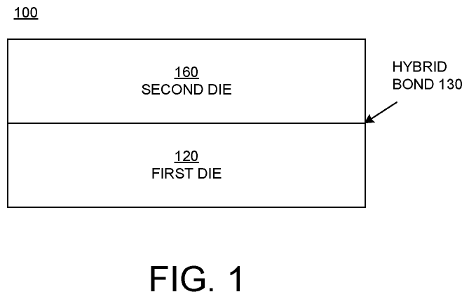

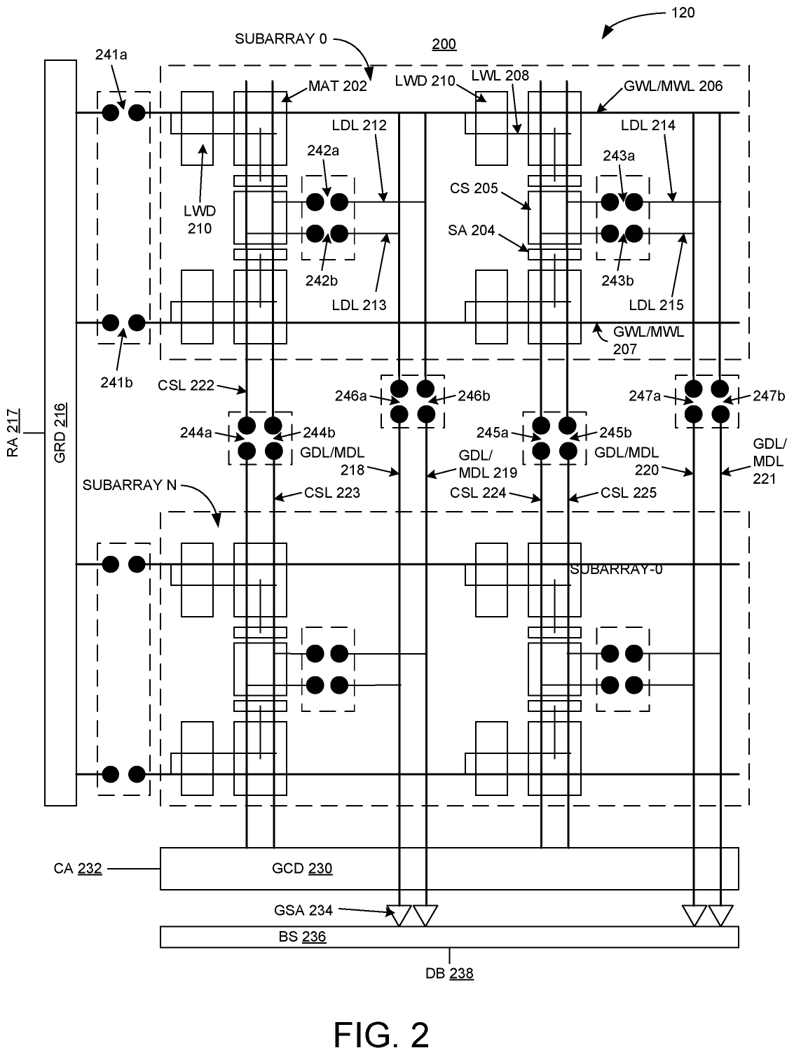

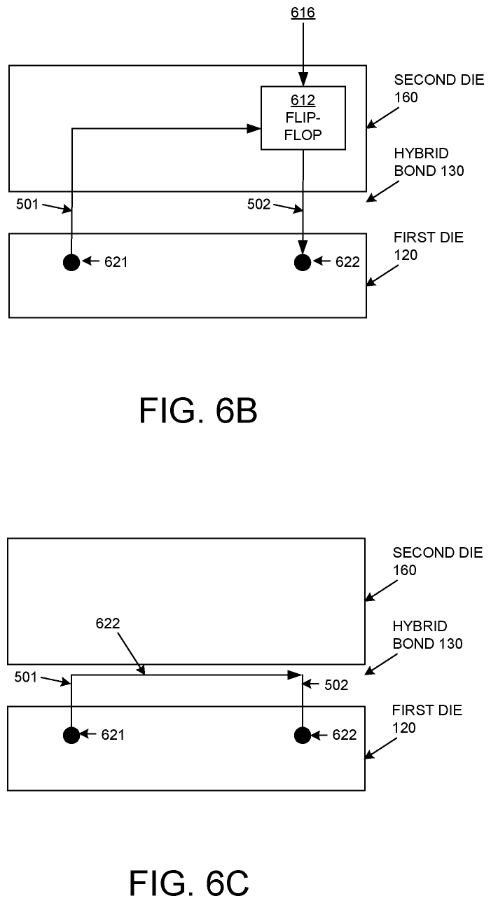

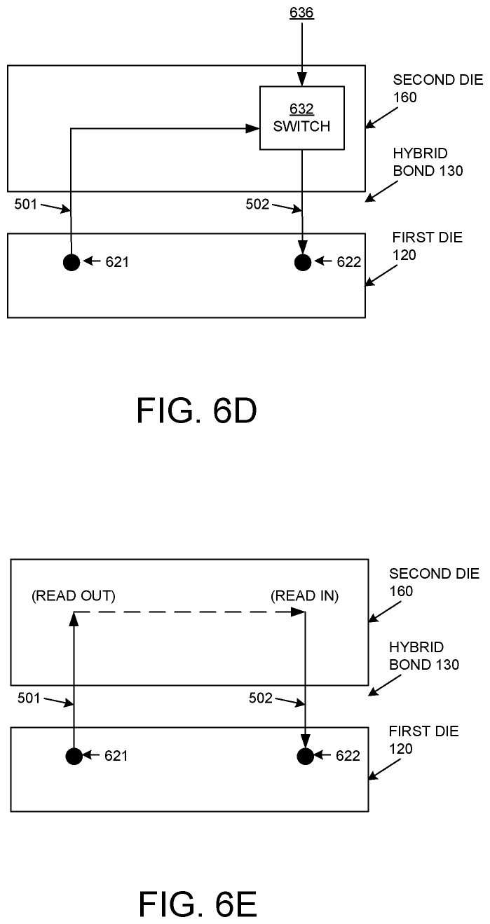

FIG. 1 is a block diagram illustrating a configurable computer memory architecture 100 in embodiments according to the present invention. The computer memory architecture 100 includes a first die 120 that is described further in conjunction with FIG. 2. The computer memory architecture 100 also includes a second die 160 that is described further in conjunction with FIGS. 6A-6E. The first die 120 and the second die 160 are bonded to each other with a bonding layer 130. In embodiments, the computer memory architecture may be referred to as three-dimensional dynamic random access memory (3D-DRAM).

In an embodiment, the bonding layer 130 is a hybrid bonding layer. Hybrid bonding, in general, describes a type of bonding that combines metal interconnects with some other form of bonding (e.g., silicon fusion bonding). That is, a hybrid bond can include wiring, for example, that permits communication between layers that are bonded by the hybrid bond.

FIG. 2 is a block diagram illustrating a memory device 200 that is disposed or implemented on the first die 120 of FIG. 1, in embodiments according to the present invention. The memory device 200 may be DRAM. FIG. 2 shows only an example portion of the memory device 200, example components of the memory device, and example numbers of those components; however, the present invention is not limited to these examples.

Generally speaking, the memory device 200 includes arrays of memory cells or memory matrices, word lines, column select lines, and data lines (including local and non-local data lines). More specifically, in embodiments, the memory device 200 includes a number of subarrays including subarray 0 and subarray N, where N is an integer. There can be any practical number of subarrays disposed between the subarray 0 and the subarray N.

In embodiments, each of the subarrays 0-N includes the following components, arranged as shown in the example of FIG. 2: a number of memory cells or memory matrices, exemplified by the memory matrix (MAT) 202; a number of sense amplifiers coupled to the MATs, exemplified by the sense amplifier (SA) 204; a number of column selectors, exemplified by the column selector (CS) 205; a number of global or master word lines (GWLs/MWLs), exemplified by the GWLs/MWLs 206 and 207; a number of local word lines, exemplified by the local word line (LWL) 208; a number of local word line decoders, exemplified by the LWL decoder (LWD) 210; and a number of local data lines, exemplified by the local data lines (LDLs) 212, 213, 214, and 215. The GWLs/MWLs are coupled to a global row decoder (GRD) 216, which receives row addresses (RA) 217.

The subarrays 0-N are traversed by a number of global or master data lines (GDLs/MDLs), exemplified by the GDLs/MDLs 218, 219, 220, and 221; and by a number of column select lines (CSLs), exemplified by the CSLs 222, 223, 224, and 225.

The memory device 200 also includes a global column decoder (GCD) 230 coupled to the CSLs and that receives column addresses (CA) 232; global SAs, exemplified by the global SA (GSA) 234; and a burst selector (BS) 236 that is coupled to the GDLs/MDLS and to a data bus (DB) 238.

In embodiments according to the present invention, one or more of the word lines, column select lines, and data lines of the memory device 200 are separated into a first segment and a second segment separated by a gap or opening. The gap prevents transmission of an electrical signal from the first segment to the second segment. However, as will be described further below, signals can be transmitted between two such segments (e.g., from one segment to the other), or prevented from being transmitted between two such segments, depending on how the computer memory architecture 100 (FIG. 1) is configured.

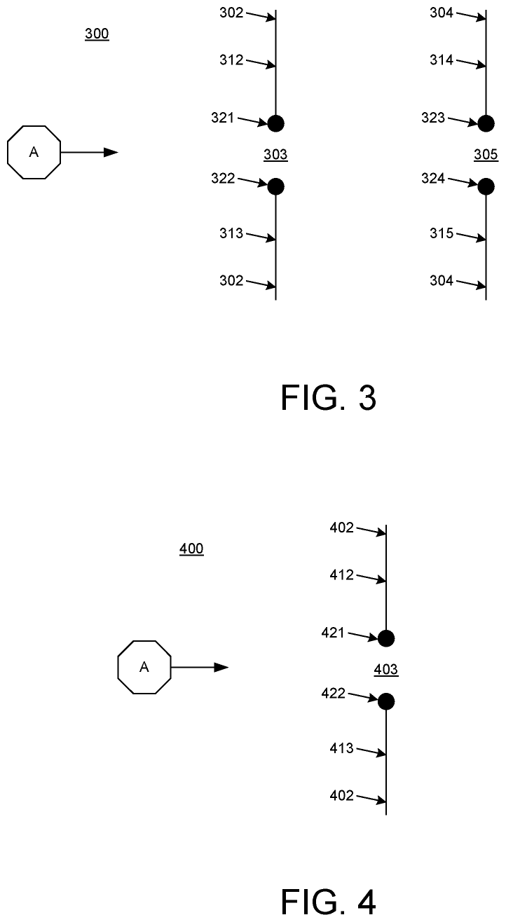

In the example of FIG. 2, a gap 241a is located on the GWL/MWL 206, a gap 241b is located on the GWL/MWL 207, a gap 242a is located on the LDL 212, a gap 242b is located on the LDL 213, a gap 243a is located on the LDL 214, a gap 243b is located on the LDL 215, a gap 244a is located on the CSL 222, a gap 244b is located on the CSL 223, a gap 245a is located on the CSL 224, a gap 245b is located on the CSL 225, a gap 246a is located on the GDL/MDL 218, a gap 246b is located on the GDL/MDL 219, a gap 247a is located on the GDL/MDL 220, and a gap 247b is located on the GDL/MDL 221. Additional information is provided below in conjunction with FIGS. 3 and 4.

Continuing with reference to FIG. 2, in different embodiments, a subarray such as the subarray 0 may or may not include all of the gaps 241a, 241b, 242a, 242b, 243a, and 243b (241-243). In different embodiments, other subarrays such as the subarray N may or may not include gaps like the gaps 241-243. In other words, in embodiments according to the present invention, a particular subarray may include none, some, or all of the gaps 241-243, and not all subarrays may be configured in the same manner with respect to the presence or location of such gaps.

Also, in different embodiments, gaps like the gaps 244a, 244b, 245a, 245b, 246a, 246b, 247a, and 247b (244-247) may or not be located on the CSLs and GDLs/MDLs between adjacent subarrays in the manner of the example of FIG. 2. In other words, in different embodiments, a gap may be located on none, some, or all of the CSLs, and a gap may be located on none, some, or all of the GDLs/MDLs.

Thus, a memory device in embodiments according to the present invention may include only some of the gaps shown in the example of FIG. 2, or it may include all of the gaps shown in the example of FIG. 2.

Each of the gaps 241-243 and 244-247 separates a respective line (e.g., a word line, column select line, or data line) of the memory device 200 into a first segment and a second segment. That is, the first segment and the second segment of a line in the memory device 200 that are separated by a gap are not connected to each other, except as will be described further below in conjunction with the examples of FIGS. 6A-6E. As will be described in those examples, signals are either transmitted between the two segments or prevented from being transmitted between the two segments depending on how the memory architecture 100 (FIG. 1) is configured.

FIG. 3 shows a top-down view of an example 300 of two parallel lines 302 and 304 in the memory device 200 (FIG. 2) that are each separated into two segments, in embodiments according to the present invention. With reference also to FIG. 2, the first line 302 and the second line 304 may be the GWLs/MWLs 206 and 207, LDLs 212 and 213 and/or 214 and 215, GDLs/MDLs 218 and 219 and/or 220 and 221, and/or CSLs 222 and 223 and/or 224 and 225. A gap 303 separates the first line 302 into a first segment 312 and a second segment 313, and another gap 305 separates the second line 304 into a first segment 314 and a second segment 315. The gaps 303 and 305 are examples of the gaps 241-247.

In the example 300 of FIG. 3, a first pin (or terminal or contact) 321 is connected to the end of the segment 312, a second pin 322 is connected to the end of the segment 313, a third pin 323 is connected to the end of the segment 314, and a fourth pin 324 is connected to the end of the segment 315. The pins 321-324 are accessible to an exterior surface of the memory device 200 (FIG. 2), allowing connections to be made to the respective ends of the segments 312-315. As will be described further below, an electrical connection between the pins 321 and 322, and/or an electrical connection between the pins 323 and 324, can be made by appropriate configuration of the memory architecture 100 (FIG. 1).

FIG. 4 shows a top-down view of an example 400 of a single line 402 in the memory device 200 (FIG. 2) that is separated into a first segment 412 and a second segment 413, in embodiments according to the present invention. The line 402 may be any one of the lines presented above (e.g., the GWLs/MWLs, LDLs, GDLs/MDLs, and CSLs of FIG. 2). A gap 403 separates the line 402 into a first segment 412 and a second segment 413. The gap 403 is an example of the gaps 241-247.

In the example 400 of FIG. 4, a first pin (or contact) 421 is connected to the end of the segment 412, and a second pin 422 is connected to the end of the segment 413. The pins 421 and 422 are accessible on an exterior surface of the memory device 200 (FIG. 2), allowing connections to be made to the respective ends of the segments 412 and 413. As will be described further below, an electrical connection between the pins 421 and 422 can be made by appropriate configuration of the memory architecture 100 (FIG. 1).

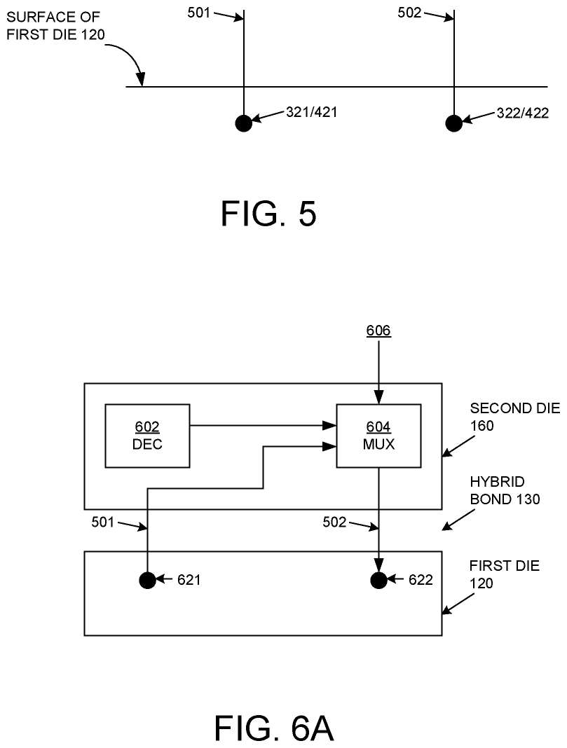

FIG. 5 illustrates a side-view (relative to the top-down view) of the examples 300 and 400 of FIGS. 3 and 4, in embodiments according to the present invention. The side-view is from point A of FIGS. 3 and 4. In embodiments, a first connector 501 is connected to the first pin 321 or 421, and a second connector 502 is connected to the second pin 322 or 422, of the examples 300 and 400. The first connector 501 and the second connector 502 extend from the second die 160 (FIG. 1) into and through the hybrid bonding layer 130. In a similar manner, a third connector (not shown) can also be connected to the third pin 323, and a fourth connector (not shown) can be connected to the fourth pin 324, of the example 300. As mentioned above, the pins 321/322/421/422 are accessible from outside the first die 120. In the example of FIG. 5, the pins 321/322/421/422 are below the surface of the first die 120 and the connectors 501 and 502 extend into the first die 120. Alternatively, the pins 321/322/421/422 can be on the surface of the first die 120, or open (exposed) to that surface.

FIGS. 6A-6E illustrate examples of different configurations of the memory architecture 100, in embodiments according to the present invention. In general, the examples of FIGS. 6A-6D show different ways that the line segments described above can be connected, by bridging the gaps between those line segments, and the example of FIG. 6E shows an example of how the pins on those line segments can be used to read out data or read in data. In FIGS. 6A-6E, the pins 622 and 644 correspond to, for example, the pins 321/322/421/422 of FIGS. 3 and 4.

In the example of FIG. 6A, the second die 160 includes a multiplexer (MUX) 604 that is coupled to the first connector 501 and to the second connector 502 through the hybrid bonding layer 130. The multiplexer 604 is operable for connecting the first connector 501 and the second connector 502 under control of an input signal 606. That is, in this example, the first connector 501 can be connected to the second connector 502, or the first connector can be disconnected from the second connector, depending on the value of the input signal 606. In an embodiment, the second die 160 includes a decoder (DEC) 602 coupled to the multiplexer 604, and the multiplexer is also operable for connecting the decoder and the second connector 502 and for selecting between an input from the first connector 501 and an input from the decoder under control of the input signal 606. Thus, in this example, a signal from the first connector 501 or a signal from the decoder 602 can be selected and provided to the second connector 502, depending on the value of the input signal 606.

In the example of FIG. 6B, the second die 160 includes a flip-flop (or register) 612 that is coupled to the first connector 501 and to the second connector 502 through the hybrid bonding layer 130. The flip-flop 612 is operable for connecting the first connector 501 and the second connector 502 under control of an input signal 616. That is, in this example, the first connector 501 can be connected to the second connector 502, or the first connector can be disconnected from the second connector, depending on the value of the input signal 616.

In the example of FIG. 6C, the first connector 501 is connected to the second connector 502 by a connector 622. In the illustrated example, the connector 622 is in the hybrid bonding layer 130; however, the connector 622 may instead by located in the second die 160.

In the example of FIG. 6D, the second die 160 includes a switch 632 that is coupled to the first connector 501 and to the second connector 502 through the hybrid bonding layer 130. The switch 632 is operable for connecting the first connector 501 and the second connector 502 under control of an input signal 636. That is, in this example, the first connector 501 can be connected to the second connector 502, or the first connector can be disconnected from the second connector, depending on the value of the input signal 636.

In the example of FIG. 6E, the second die 160 is operable for receiving (reading) an input from the first connector 501 through the hybrid bonding layer 130. In embodiments, the second die 160 is operable for sending (writing) an input to the second connector 502 through the hybrid bonding layer 130. The input written to the second connector 502 may be or may not be the input read from the first connector 501.

The examples of FIGS. 6A-6E may be used in different combinations to configure the memory architecture 100 (FIG. 1) in different ways for different use cases. Table 1 provides examples of how the memory architecture 100 can be configured in different ways for different use cases. Embodiments according to the present invention are not limited to the examples of Table 1.

TABLE 1
Example Configurations

| | | Pseudo- | | Half- | Higher | tCCD |
|---|---|---|---|---|---|---|
| | DDR | bank | SLP | DRAM | BW | Opt |
| GWL | 6C | 6C | 6A, 6B, | 6C | 6A, 6B, | 6C |
| | | | or 6C | | or 6C | |
| CSL | 6C | 6C | 6C | 6A | 6A or 6C | 6D |
| GDL | 6C | 6D | 6C | 6C | 6E | 6D |
| LDL | 6C | 6C | 6D | 6C | 6C | 6C |

In Table 1, DDR refers to double data rate, a pseudo-bank emulates a fast memory bank but is not an actual memory bank, SLP refers to sub-level parallelism, half-DRAM refers to an architecture in which a DRAM is organized so that only half a row is activated, high BW refers to High Bandwidth Memory (HBM), and tCCD Opt refers to optimization of tCCD (the column command delay). The entries in the columns/rows of Table 1 refer to the figures herein; for example, “6C” refers to FIG. 6C. An example of how to read Table 1 is as follows: to configure the memory architecture 100 (FIG. 1) as HBM, the GWL segments of FIG. 2 are connected using the configuration of FIG. 6A, 6B, or 6C; the CSL segments of FIG. 2 are connected using the configuration of FIG. 6A or 6C; the GDL segments of FIG. 2 are connected using the configuration of FIG. 6E; and the LDL segments of FIG. 2 are connected using the configuration of FIG. 6C.

With reference also to FIG. 1, note that the physical layouts of the dies 120 and 160 described above are formed during the respective fabrication of those dies. Also, in embodiments based on the examples of FIGS. 6A, 6B, and 6D, the configuration of the die 160 depends on the value of the input signals 606, 616, and 636, respectively. Different computer memory architectures can be formed by assembling the die 120 with the different versions of the die 160. In other words, while the die 120 and the different versions of the die 160 are each standardized, the die 120 can be combined with a version of the die 160 that is selected and configured based on a user's needs or preferences, to produce a computer memory architecture that is customized according to the user's intended use case or cases.

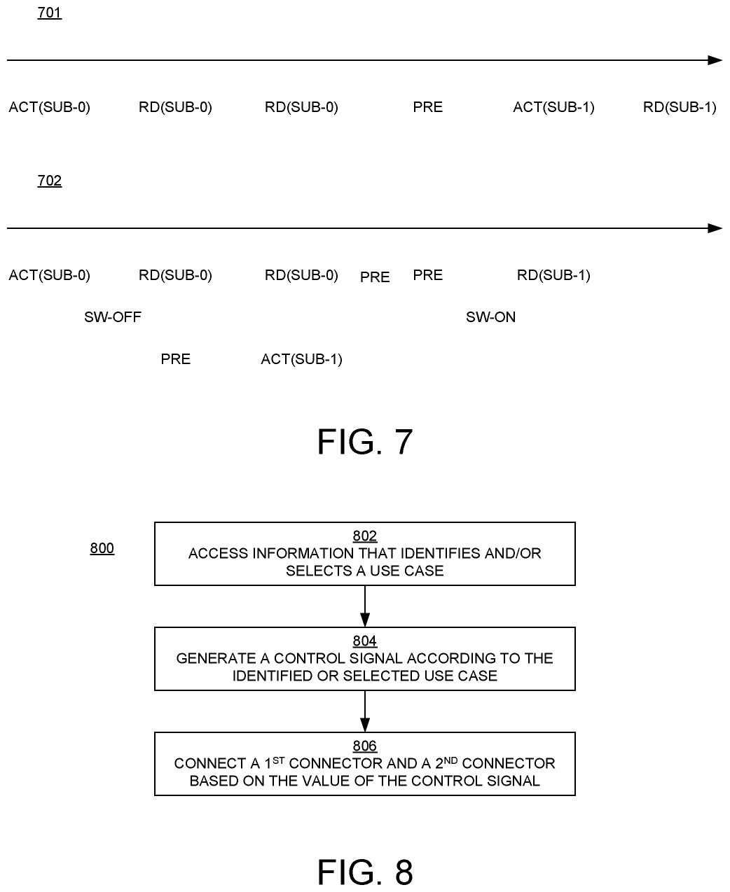

In addition to other advantages and benefits described herein, architectures in embodiments according to the present invention provide benefits such as the following. The pseudo-bank and SLP architectures in embodiments according to the present invention advantageously hide activation (see the example of FIG. 7), increase bandwidth utilization, and reduce latency. The half-DRAM architecture in embodiments according to the present invention advantageously reduces activation power, is flexible, and increases bandwidth utilization. The high BW architecture in embodiments according to the present invention increases input/output at the subarray level. The tCCD Opt architecture in embodiments according to the present invention reduces tCCD latency when accessing a predefined memory region.

FIG. 7 includes two timelines 701 and 702 showing a comparison of a sequence of signals for a conventional 3D-DRAM architecture versus a 3D-DRAM configured as a pseudo-bank architecture in an embodiment according to the present invention. As seen in Table 1, in the pseudo-bank architecture, the GWL segments, CSL segments, and LDL segments of FIG. 2 are connected using the configuration of FIG. 6C, and the GDL segments of FIG. 2 are connected using the configuration of FIG. 6D (using the switch 632).

With reference to FIG. 7, in the timeline 701 for a conventional 3D-DRAM, an activation signal (ACT) for a subarray (e.g., SUB-0) is sent; a double-read (RD) of the subarray is signaled; a precharging signal (PRE) is sent; followed by an activation signal for a second subarray (e.g., SUB-1) and a read signal for the second subarray. In the timeline 702 for a 3D-DRAM configured as a pseudo-bank architecture in an embodiment according to the present invention, an activation signal for a subarray (e.g., SUB-0) is sent; the switch 632 is turned off (SW-OFF); a double-read of the subarray is signaled and, in parallel, a precharge signal followed by an activation signal for a second subarray (e.g., SUB-1) are sent; a precharge signal is sent; the switch 632 is turned on (SW-ON); and a read of the second subarray is signaled. Thus, for the 3D-DRAM configured as a pseudo-bank architecture in an embodiment according to the present invention, the first precharging signal and the activation signal for the second array, and consequently the read signal for the second array, are sent earlier than the corresponding signals for the conventional architecture.

FIG. 8 is a flowchart 800 of an example of a method of configuring the computer memory architecture 100 of FIG. 1, in embodiments according to the present invention.

In block 802 of FIG. 8, information that identifies and/or selects a use case for the computer memory architecture 100 is accessed.

In block 804, a control signal is generated according to the identified or selected use case.

In block 806, a component disposed in the second die 160 of the computer memory architecture 100 (FIG. 1) is controlled to connect the first connector 501 to the second connector 502 (FIG. 5) based on a value of the control signal.

In an embodiment, with reference to FIG. 6A, the component disposed in the second die 160 is the multiplexer 604, which is controlled by the signal 606 to select an input from the first connector 501 and send the input from the first connector to the second connector 502. In such an embodiment, the second die also includes the decoder 602, in which case the multiplexer 604 is controlled by the signal 606 to select an input from the decoder (instead of from the first connector 501) and send the input from the decoder to the second connector 502.

In an embodiment, with reference to FIG. 6B, the component disposed in the second die 160 is the flip-flop 612, which is controlled by the signal 616 to connect the first connector and the second connector.

In an embodiment, with reference to FIG. 6D, the component disposed in the second die 160 is the switch 632. In this embodiment, the switch 632 is controlled by the signal 636 to turn on the switch to connect the first connector 501 and the second connector 502, and to turn off the switch to disconnect the first connector from the second connector.

The process parameters and sequence of steps described and/or illustrated herein are given by way of example only and can be varied as desired. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

Although the subject matter has been described in language specific to structural features and/or methodological acts, it is to be understood that the subject matter defined in the present disclosure is not necessarily limited to the specific features or acts described above. Rather, the specific features and acts described above are disclosed as example forms of implementing the present disclosure.

Embodiments according to the invention are thus described. While the present disclosure has been described in particular embodiments, the invention should not be construed as limited by such embodiments, but rather construed according to the following claims.

What is claimed is:

1. A computer system memory device, comprising:
a plurality of arrays of memory cells; and
a plurality of lines coupled to the arrays of memory cells, wherein the plurality of lines comprises a plurality of word lines, a plurality of column select lines, and a plurality of data lines;
wherein a first line of the plurality of lines comprises a first segment and a second segment that are separated by a first gap that prevents transmission of an electrical signal from the first segment to the second segment.

2. The computer system memory device of claim 1, further comprising a first pin connected to the first segment of the first line and a second pin connected to the second segment of the first line, wherein the first pin and the second pin are accessible to an exterior surface of the computer system memory device.

3. The computer system memory device of claim 1, wherein the first line is a first word line for a first memory cell and a second memory cell of an array of the plurality of arrays, wherein a second word line for the first memory cell and the second memory cell comprises a first segment and a second segment that are separated by a second gap that prevents transmission of an electrical signal from the first segment of the second word line to the second segment of the second word line.

4. The computer system memory device of claim 1, wherein the first line is a first column select line coupled to an array of the plurality of arrays, wherein a second column select line coupled to the array comprises a first segment and a second segment that are separated by a second gap that prevents transmission of an electrical signal from the first segment of the second column select line to the second segment of the second column select line.

5. The computer system memory device of claim 1, wherein the first line is a first global data line coupled to an array of the plurality of arrays, wherein a second global data line coupled to the array comprises a first segment and a second segment that are separated by a second gap that prevents transmission of an electrical signal from the first segment of the second global data line to the second segment of the second global data line.

6. The computer system memory device of claim 1, wherein the first line is a local data line for a memory cell of an array of the plurality of arrays, wherein a second local data line coupled to the memory cell comprises a first segment and a second segment that are separated by a second gap that prevents transmission of an electrical signal from the first segment of the second local data line to the second segment of the second local data line.

7. A configurable computer memory architecture, comprising:
a first die comprising:
a plurality of arrays of memory cells;
a plurality of lines coupled to the arrays of memory cells, wherein the plurality of lines comprises a plurality of word lines, a plurality of column select lines, and a plurality of data lines, wherein a first line of the plurality of lines comprises a first segment and a second segment that are separated by a first gap that prevents transmission of an electrical signal from the first segment to the second segment;
a first pin connected to the first segment of the first line; and
a second pin connected to the second segment of the first line;
a second die coupled to the first die; and
a first connector coupled to the first pin.

8. The configurable computer memory architecture of claim 7, wherein the first line is a first word line for a first memory cell and a second memory cell of an array of the plurality of arrays, wherein a second word line for the first memory cell and the second memory cell comprises a first segment and a second segment that are separated by a second gap that prevents transmission of an electrical signal from the first segment of the second word line to the second segment of the second word line.

9. The configurable computer memory architecture of claim 7, wherein the first line is a first column select line coupled to an array of the plurality of arrays, wherein a second column select line coupled to the array comprises a first segment and a second segment that are separated by a second gap that prevents transmission of an electrical signal from the first segment of the second column select line to the second segment of the second column select line.

10. The configurable computer memory architecture of claim 7, wherein the first line is a first global data line coupled to an array of the plurality of arrays, wherein a second global data line coupled to the array comprises a first segment and a second segment that are separated by a second gap that prevents transmission of an electrical signal from the first segment of the second global data line to the second segment of the second global data line.

11. The configurable computer memory architecture of claim 7, wherein the first line is a local data line for a memory cell of an array of the plurality of arrays, wherein the first line is a local data line for a memory cell of an array of the plurality of arrays, wherein a second local data line coupled to the memory cell comprises a first segment and a second segment that are separated by a second gap that prevents transmission of an electrical signal from the first segment of the second local data line to the second segment of the second local data line.

12. The configurable computer memory architecture of claim 7, wherein the first connector is also connected to a second connector that is coupled to the second pin.

13. The configurable computer memory architecture of claim 7, further comprising a second connector coupled to the second pin, wherein the second die comprises a flip-flop coupled to the first connector and to the second connector, and wherein the flip-flop is operable for connecting the first connector and the second connector.

14. The configurable computer memory architecture of claim 7, further comprising a second connector coupled to the second pin, wherein the second die comprises a multiplexer coupled to the first connector and to the second connector, and wherein the multiplexer is operable for connecting the first connector and the second connector.

15. The configurable computer memory architecture of claim 14, wherein the second die further comprises a decoder coupled to the multiplexer, wherein the multiplexer is also operable for connecting the decoder and the second connector, and wherein the multiplexer is also operable for selecting between an input from the first connector and an input from the decoder.

16. The configurable computer memory architecture of claim 7, further comprising a second connector coupled to the second pin, wherein the second die comprises a switch coupled to the first connector and to the second connector, and wherein the switch is operable for connecting the first connector and the second connector.

17. The configurable computer memory architecture of claim 7, wherein the second die is operable for receiving an input from the first pin over the first connector.

18. The configurable computer memory architecture of claim 17, further comprising a second connector coupled to the second pin, wherein the second die is operable for writing an input to the second pin over the second connector.

19. The configurable computer memory architecture of claim 7, further comprising a hybrid bonding layer between the first die and the second die and comprising the first connector.

20. A method of configuring a computer memory architecture, the computer memory architecture comprising:
a first die comprising:
a plurality of arrays of memory cells;
a plurality of lines coupled to the arrays of memory cells, wherein the plurality of lines comprises a plurality of word lines, a plurality of column select lines, and a plurality of data lines, wherein a first line of the plurality of lines comprises a first segment and a second segment that are separated by a first gap that prevents transmission of an electrical signal from the first segment to the second segment;
a first pin connected to the first segment of the first line; and
a second pin connected to the second segment of the first line;
a second die coupled to the first die;
a first connector coupled to the first pin; and
a second connector coupled to the second pin;
the method comprising:
accessing information to select a use case for the computer memory architecture;
generating a control signal according to the use case; and
controlling a component disposed in the second die to connect the first connector to the second connector based on a value of the control signal.

21. The method of claim 20, wherein the component disposed in the second die comprises a flip-flop coupled to the first connector and to the second connector, and wherein said controlling comprises controlling the flip-flop to connect the first connector and the second connector.

22. The method of claim 20, wherein the component disposed in the second die comprises a multiplexer coupled to the first connector and to the second connector, and wherein said controlling comprises controlling the multiplexer to select an input from the first connector and send the input from the first connector to the second connector.

23. The method of claim 22, wherein the second die further comprises a decoder coupled to the multiplexer, wherein said controlling further comprises controlling the multiplexer to select an input from the decoder and send the input from the decoder to the second connector.

24. The method of claim 20, wherein the second die comprises a switch coupled to the first connector and to the second connector, and wherein said controlling comprises:
turning on the switch to connect the first connector and the second connector; and
turning off the switch to disconnect the first connector from the second connector.
